(19) United States
(12) Patent Application Publication
(10) Pub. No.: US 2026/0107821 A1
(43) Pub. Date: Apr. 16, 2026

(54) DISPLAY DEVICES

(71) Applicant: Wuhan China Star Optoelectronics Semiconductor Display Technology Co., Ltd., Wuhan (CN)

(72) Inventor: Wenqiang WANG, Wuhan (CN)

(73) Assignee: Wuhan China Star Optoelectronics Semiconductor Display Technology Co., Ltd., Wuhan (CN)

(21) Appl. No.: 18/270,300

(22) Filed: Jun. 29, 2023

Related U.S. Application Data
(63) Continuation of application No. PCT/CN2023/093858, filed on May 12, 2023.

(30) Foreign Application Priority Data
Mar. 30, 2023 (CN) 202310331643.3

(51) Int. Cl. H10W 74/10; H10W 74/47

(52) U.S. Cl. CPC H10W 74/121; H10W 74/476

(57) ABSTRACT

The present application provides a display device. The display device includes a display panel and an impact-resistance layer. The impact-resistance layer includes at least two sub-layers, two adjacent sub-layers of the sub-layers are bonded by an adhesive layer, the at least two sub-layers includes a first sub-layer and a second sub-layer between the first sub-layer and the display panel, the ratio of the elastic modulus of the first sub-layer to the elastic modulus of the second sub-layer is 20 to 300, and the material of the first sub-layer is different from the material of the second sub-layer.

### CROSS-REFERENCE TO RELATED APPLICATION(S)

This application is a Continuation Patent Application of PCT Application No. PCT/CN2023/093858, filed on May 12, 2023, which claims the benefit of priority of Chinese Patent Application No. 202310331643.3, filed on Mar. 30, 2023. The disclosures of the aforementioned applications are incorporated herein by reference in their entireties.

### TECHNICAL FIELD

The present application relates to the field of display technologies, and more particularly to a display device.

### BACKGROUND

The service life and durability of display devices are important parameters of product quality. If the ability of the outermost protective cover of the display devices to withstand an external impact force, especially for the outward-folding display device where a display panel is closer to the outside and more susceptible to impact of a foreign object such as shock, collision, and falling is insufficient, it will put the service life of the display devices to the test.

Therefore, there is an urgent need for a display device to solve the above-mentioned technical problem.

### SUMMARY

An embodiment of the present application provides a display device including: a display panel; and an impact-resistance layer provided on a light-emitting side of the display panel; where the impact-resistance layer includes at least two sub-layers, two adjacent sub-layers of the sub-layers are bonded by an adhesive layer, the at least two sub-layers include a first sub-layer and a second sub-layer located on one side of the first sub-layer close to the display panel, the ratio of an elastic modulus of the first sub-layer to an elastic modulus of the second sub-layer is 20 to 300, and a material of the first sub-layer is different from a material of the second sub-layer.

### BRIEF DESCRIPTION OF THE DRAWINGS

FIG. 1 is a schematic structural diagram of a structure of a display device according to an embodiment of the present application.

FIG. 2 is a schematic structural diagram of another structure of a display device according to another embodiment of the present application.

FIG. 3 is a schematic diagram showing an overall structure in a process of a drop ball test of a display device according to an embodiment of the present application.

FIG. 4 is a schematic diagram showing propagation of an impact stress wave in the interior of two different materials in a process of a drop ball test of a display device according to an embodiment of the present application.

FIG. 5 is a schematic diagram showing propagation of an impact stress wave of a drop ball within different stack designs in a process of a drop ball test of a display device according to an embodiment of the present application.

FIG. 6 is a schematic diagram showing arrangement of a test point in a process of a drop ball test of a display device according to an embodiment of the present application.

FIG. 7 is a schematic diagram showing a drop ball impact mechanics simulation in a process of a drop ball test of a display device according to an embodiment of the present application.

FIG. 8 is a schematic diagram showing propagation of a stress wave in two different directions inside a display device in a process of a drop ball test of the display device according to an embodiment of the present application.

FIG. 9 is a partial structural diagram of a bending region of a display device according to an embodiment of the present application.

### DETAILED DESCRIPTION

The present application provides a display device. To make the objectives, technical solutions, and effects of the present application more clear and definite, the present application is illustrated in detail below by referring to the accompanying drawings and illustrating the embodiments. It should be understood that the specific implementations described here are only used to explain the present application, and are not used to limit the present application.

An embodiment of the present application provides a display device. Detailed descriptions are given below. It should be noted that the description order of the following embodiments is not intended to limit the preferred order of the embodiments.

The service life and durability of display devices are important parameters of product quality. If the ability of the outermost protective cover of the display devices to withstand an external impact force, especially for the outward-folding display device where a display panel is closer to the outside and more susceptible to impact of a foreign object such as shock, collision, and falling is insufficient, it will put the service life of the display devices to the test.

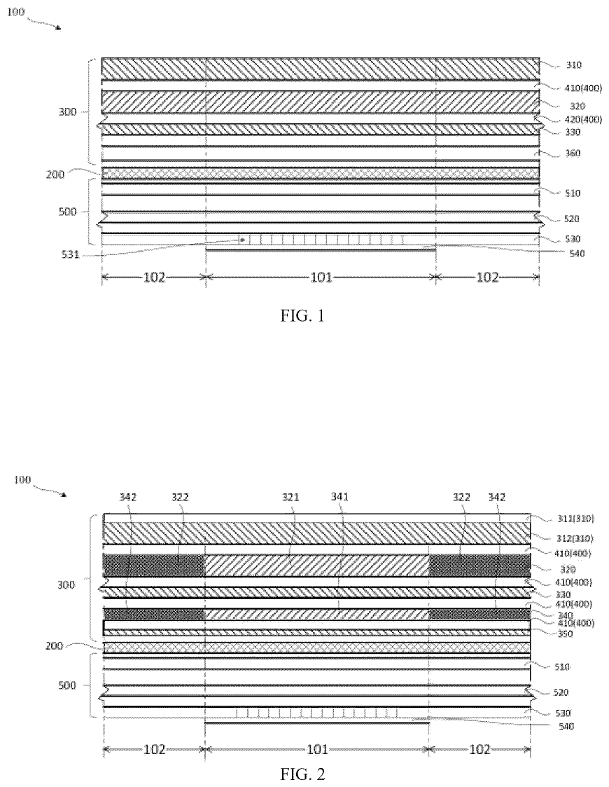

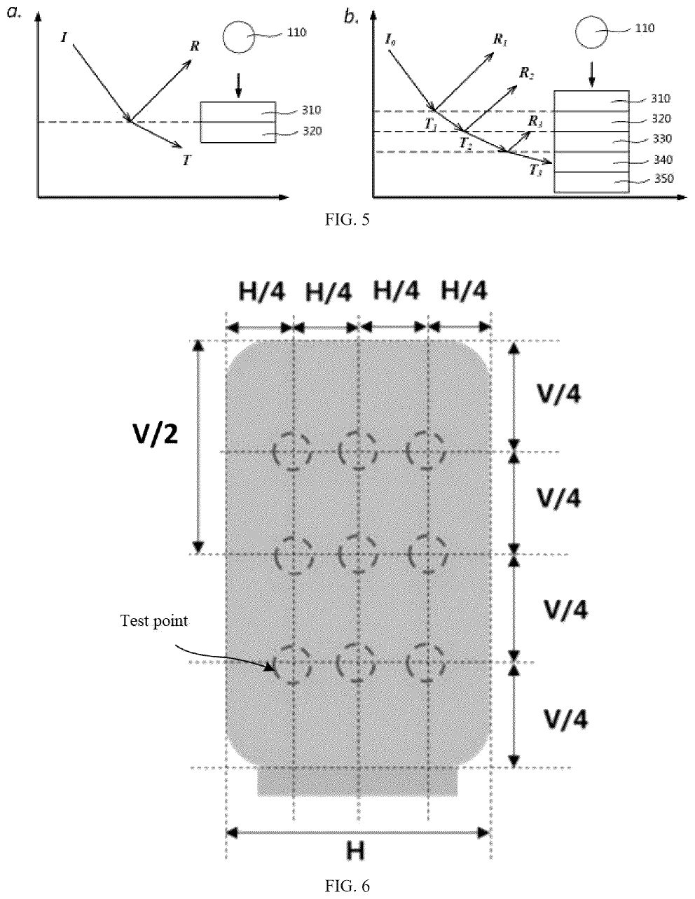

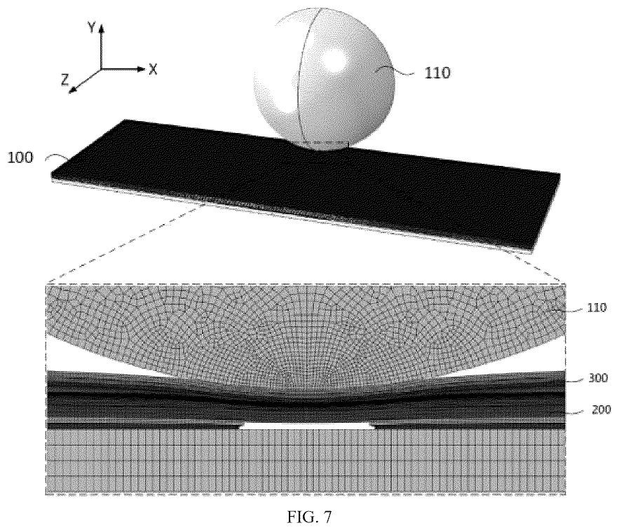

Referring to FIGS. 1-9, an embodiment of the present application may provide a display device 100, including: a display panel 200; and an impact-resistance layer 300 provided on a light-emitting side of the display panel 200; where the impact-resistance layer 300 may include at least two sub-layers, two adjacent sub-layers of the sub-layers are bonded by an adhesive layer 400, the at least two sub-layers include a first sub-layer 310 and a second sub-layer 320 located on one side of the first sub-layer 310 close to the display panel 200, the ratio of an elastic modulus of the first sub-layer 310 to an elastic modulus of the second sub-layer 320 may be 20 to 300, and a material of the first sub-layer 310 may be different from a material of the second sub-layer 320.

In the present application, an impact-resistance layer including at least two sub-layers respectively having a high elastic modulus and a low elastic modulus is disposed on a display panel. When the display device is impacted, an impact energy is propagated in a stress wave including a lateral stress wave and a longitudinal stress wave in a lateral direction and a longitudinal direction. The stress wave first contacts the high elastic modulus film layer to rapidly propagate the lateral stress wave within the plane of the first sub-layer, and the lateral stress wave can be rapidly absorbed by a smaller deformation of the first sub-layer. The longitudinal stress wave continues to be propagated inward in a direction perpendicular to the display device, and when the longitudinal stress wave contacts the second sub-layer having the low elastic modulus, the impact energy can be easily absorbed by a larger deformation of the second sub-layer. Meanwhile, the stress wave is more easily propagated in the film layer having a larger elastic modulus, and since the elastic modulus of the second sub-layer is greater than the elastic modulus of the first sub-layer, the longitudinal stress wave is more easily reflected back to the first sub-layer, thereby slowing the tendency that the longitudinal stress wave is further propagated inward in the direction perpendicular to the display device and being more advantageous to protect the display panel and prolong the service life of the display device.

Technical solutions of the present application will be described now in conjunction with specific embodiments of the present application.

In some embodiments, referring to FIG. 1, the impact-resistance layer 300 may further include an adhesive layer 400 disposed between two adjacent sub-layers of the sub-layers. For example, referring to FIG. 1, the impact-resistance layer 300 may further include a first adhesive layer 410 disposed between the first sub-layer 310 and the second sub-layer 320, and a second adhesive layer 420 disposed between the second sub-layer 320 and a third sub-layer 330. The adhesive layer 400 may be an optical adhesive layer.

If the thickness of the impact-resistance layer 300 is simply increased, the impact resistance of the display device 100 can be improved. However, an overall neutral layer of the display device 100 may be offset. Therefore, in order for the neutral layer to be closer to the display panel 200, a thicker film layer needs to be disposed on a backlight side of the display panel 200, so that the overall thickness of the display device 100 may be thickened. On the one hand, it is not conducive to thinning of the display device 100. On the other hand, for a folding display device 100, the larger thickness of the display device 100 is also not conducive to bending of the display device 100.

Referring to FIGS. 1 and 4, when the display device 100 is subjected to an external impact load or an instantaneous impact, the outermost layer of the display device may be first subjected to an impact, and an impact energy may be propagated inside the outermost layer in the form of a stress wave including a lateral stress wave and a longitudinal stress wave laterally (in-plane) and longitudinally (in a direction perpendicular to a thickness direction) along the film layer.

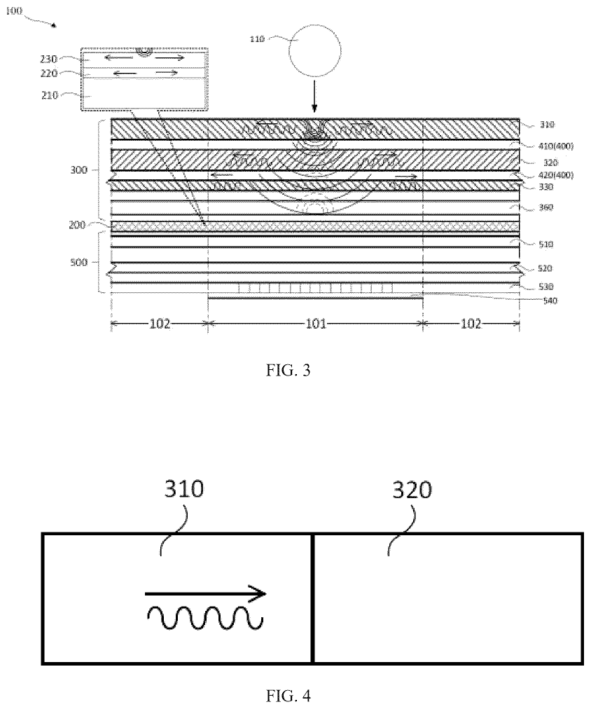

Referring to FIG. 3, a modulus of the uppermost first sub-layer 310 is relatively high, and the lateral stress wave is propagated rapidly in the plane of the first sub-layer 310. A lateral material area of the first sub-layer 310 is greater than that in the thickness direction, and the lateral stress wave can be rapidly absorbed by a smaller deformation of the first sub-layer 310. That is, the lateral impact stress wave may release or diffuse the stress to a distal end of an impact region as the first sub-layer 310 is vibrated or deformed in the plane.

Referring to FIGS. 3 and 5, the longitudinal stress waves continue to be propagated in the thickness direction of the display device 100. Since the modulus of the second sub-layer 320 is relatively low, the impact energy may be more easily absorbed by the larger deformation of the second sub-layer, thereby reducing the tendency that the longitudinal stress wave is further propagated in the thickness direction.

Referring to FIG. 4, when a stress wave is propagated from a high modulus material layer (for example, the first sub-layer 310) to a low modulus material layer (for example, the second sub-layer 320), reflection and transmission phenomena occur at an adjacent interface due to different impedance characteristics of the two materials (similar to light propagation characteristics of glass and water). The difference in propagation of the stress wave near the two film layers may be caused by the impedance difference between the two materials. The greater the impedance difference between the two materials, the stronger the reflection wave, and the less the stress waves that are transmitted into the low modulus layer and the more the stress waves that are returned reversely.

Referring to FIG. 5, an impedance of a wave may be directly proportional to a density of a material and a velocity of the wave, where the velocity is directly related to the modulus of the material itself, and the stress wave is more easily propagated in a film layer having a larger modulus. Since the elastic modulus of the second sub-layer 320 differs greatly from the elastic modulus of the first sub-layer 310, the longitudinal stress wave is more easily reflected back to the first sub-layer 310, where I denotes a stress wave, R denotes a reflected wave, and T denotes a transmitted wave, as shown in FIG. 5.

If a difference between the elastic modulus of the second sub-layer 320 and the elastic modulus of the first sub-layer 310 is too small, it is not conducive to reflection of the longitudinal stress wave back to the first sub-layer 310 to protect the display panel 200, which may cause more longitudinal stress waves to penetrate the display device 100. If the difference between the elastic modulus of the second sub-layer 320 and the elastic modulus of the first sub-layer 310 is too large, that is, the elastic modulus of the second sub-layer 320 is too small, for example, some adhesive layers, such as an optically clear adhesive (OCA) glue may have an elastic modulus in the order of Kpa, it is difficult to evacuate and absorb an impact energy by in-plane vibration of the second sub-layer 320 due to inherent viscous flow characteristics of the second sub-layer 320 when subjected to an impact.

By disposing the impact-resistance layer 300 including at least two sub-layers respectively having a high elastic modulus and a low elastic modulus on the display panel 200, two main lines of defense against the impact are formed, which prolongs the service life of the display device 100, and the elastic modulus of the second sub-layer 320 is small for the folding display device 100, thereby facilitating bending of the display device 100.

The elastic modulus is independent of humidity and there is no significant change in the elastic modulus of the material at a normal temperature (20° C. to 35° C.), so that limitation of the elastic modulus described herein is defined at the normal temperature (20° C. to 35° C.).

In some embodiments, referring to FIG. 3, the display panel 200 may include a panel body 210, an encapsulation layer 220, and a touch layer 230.

Referring to FIGS. 2, 6-7, and 9, a drop ball test may be performed by using the folding display device 100 as an example. A test that the impact resistance of the folding display device 100 may be performed with the drop ball 110 may be performed with reference to GB15763.2-2005 standard. A steel ball with a diameter of 20 mm and a weight of 32 g may be selected as the drop ball 110. Nine measurement points to be tested are selected at the same interval between the bending region 101 and the plane region 102 of the panel body for simulation testing. Referring to an impact experiment of the actual drop ball 110, a finite element simulation method may be used to determine a failure point of the encapsulation layer 220 in the display panel 200 in combination with a stress behavior of the display device 100 under impact load. According to a failure mechanism of the encapsulation layer 220, a finite element analysis method may be used to verify and compare the differences and advantages and disadvantages of stack designs of the impact-resistance display device 100 by taking the maximum tensile strain of the encapsulation layer 220 as a reference basis.

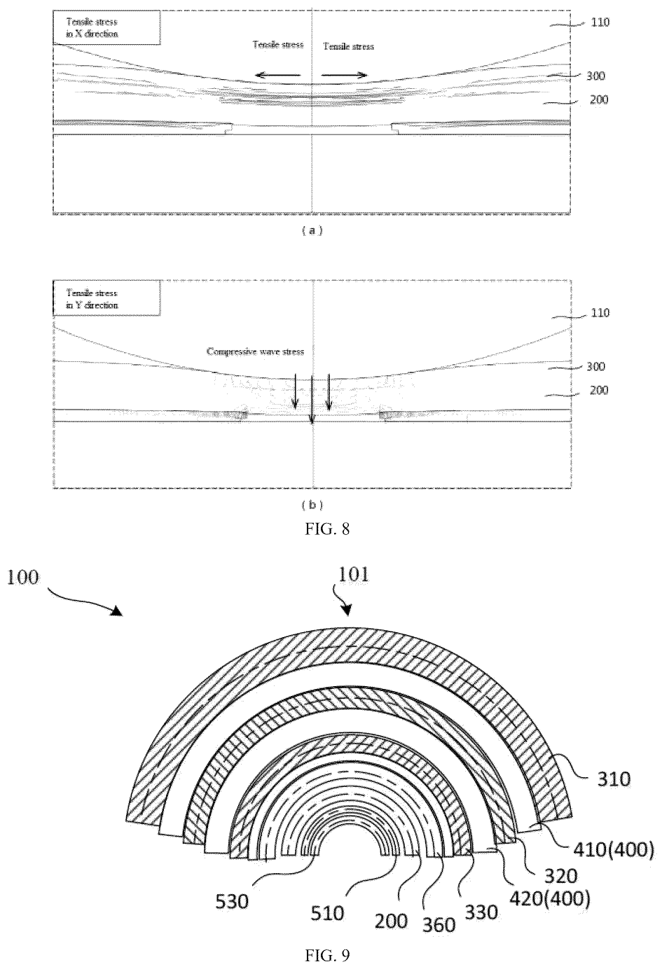

Referring to FIG. 8, it can be seen in combination with the above-mentioned impact stress wave propagation principle and by the simulation experiment that, when the impact-resistance layer 300 is subjected to impact of the drop ball 110 or the foreign object, the stress wave is first transmitted into the first sub-layer 310 and decomposed into a lateral stress wave and a longitudinal stress wave which are respectively propagated laterally (in-plane) and longitudinally (in a direction perpendicular to a thickness direction). In (a) of FIG. 8, a tensile stress is represented in the lateral direction (for example, the X direction), and in (b) of FIG. 8, a compressive wave stress is represented in the longitudinal direction (for example, the Y direction). The lateral stress wave may be gradually dissipated by vibration and deformation of the high elastic modulus material, and the longitudinal stress wave may be gradually dissipated by a deformation absorption and barrier action of the low elastic modulus material, so that excessive stress waves are prevented from being transmitted to the display panel 200.

A comparative group and experimental groups 1˜10 are simulated in which the elastic modulus of continuous polyimide (CPI) is 3500 Mpa, the elastic modulus of polyethylene terephthalate (PET) is 3500 Mpa, the elastic modulus of ultrathin glass (UTG) is 70000 Mpa, the elastic modulus of thermoplastic Polyurethane (TPU) is 200 Mpa, and the elastic modulus of polydimethylsiloxane (PDMS) is 20 Mpa. Conditions and results of the simulation are shown in Table 1.

TABLE 1

| | | | Tensile |
|---|---|---|---|
| | | Relative | strain of |
| | Film layer | Modulus | encapsulation |
| Project | (thickness/mm) | distribution | layer |
| Comparative | CPI (50) + CPI (50) | High-high | 0.895% |
| group | | | |
| Experimental | CPI (50) + PET (50) | High-high | 0.883% |
| group 1 | | | |
| Experimental | CPI (50) + PET (23) | High-high | 0.886% |
| group 2 | | | |
| Experimental | CPI (50) + UTG (30) | High-high | 0.815% |
| group 3 | | | |
| Experimental | CPI (80) + UTG (30) | High-high | 0.809% |
| group 4 | | | |
| Experimental | CPI (50) + TPU (100) | High-low | 0.656% |
| group 5 | | | |
| Experimental | CPI (50) + TPU (150) | High-low | 0.645% |
| group 6 | | | |
| Experimental | CPI (50) + TPU (200) | High-low | 0.632% |
| group 7 | | | |
| Experimental | CPI (50) + PDMS (100) | High-low | 0.513% |
| group 8 | | | |
| Experimental | CPI (50) + PDMS | High-low- | 0.422% |
| group 9 | (100) + PET (50) | high | |
| Experimental | CPI (50) + PDMS | High-low- | 0.413% |
| group 10 | (100) + PET (23) + PDMS | High-low- | |
| | (100) + PET (23) | high | |

It can be seen from the results of the simulation that the dual-layer impact-resistance layer 300 respectively having the high-high elastic modulus in the comparative group may be compared with the dual-layer impact-resistance layer 300 respectively having high-high elastic modulus in the experimental groups 1-4. If the second sub-layer 320 still has the high clastic modulus, an attenuation effect of a tensile strain (for example, Tensile Strain at Fracture Extension) of the encapsulation layer 220 of the display panel 200 may be not obvious, and tensile strain results of the five experimental groups are all 0.8% or more, which has exceeded a failure limit value of an inorganic layer in the encapsulation layer 220. That is, the double-layer structure having the high-high elastic modulus cannot effectively reduce the strength of the longitudinally conducted stress wave.

For the dual-layer impact-resistance layer 300 respectively having high-low elastic modulus in experimental groups 5 and 6, the elastic modulus of the first sub-layer may be greater than that of the second sub-layer. By lowering the elastic modulus of the second sub-layer 320, there is a significant reduction in the tensile strain of the encapsulation layer of display panel 200, indicating that the impact-resistance layer 300 having the high-low elastic modulus may be beneficial for reducing the impact stress.

With comparison among the experimental groups 5-7, increasing of the thickness of the low-modulus material does not contribute much to reduction of the strength of the stress wave, and therefore the thickness is not the main influence factor for reducing the strength of the stress wave. Moreover, if the thickness is too high, the bending characteristics of the display device may be affected.

In some embodiments, the elastic modulus of the first sub-layer may be greater than the elastic modulus of the second sub-layer, and the ratio of the elastic modulus of the first sub-layer to the elastic modulus of the second sub-layer may be 20 to 300.

If a difference between the elastic modulus of the second sub-layer 320 and the elastic modulus of the first sub-layer 310 is too small and the elastic modulus of the second sub-layer 320 is too large, it is not conducive to reflection of the longitudinal stress wave back to the first sub-layer 310 to protect the display panel 200, which may cause more longitudinal stress waves to penetrate the display device 100. If the difference between the elastic modulus of the second sub-layer 320 and the elastic modulus of the first sub-layer 310 is too large, that is, the elastic modulus of the second sub-layer 320 is too small, for example, some adhesive layers, such as an optically clear adhesive (OCA) glue may have an elastic modulus in the order of Kpa, it is difficult to evacuate and absorb an impact energy by in-plane vibration of the second sub-layer 320 due to inherent viscous flow characteristics of the second sub-layer 320 when subjected to an impact. The ratio of the elastic modulus of the first sub-layer 310 to the elastic modulus of the second sub-layer 320 is 20 to 300. For example, the ratio of a static elastic modulus of the first sub-layer 310 to a static elastic modulus of the second sub-layer 320 may be 20 to 300, e.g., any of 20, 50, 80, 100, 150, 200, 240, 250, 280, or 300.

In some embodiments, a strain rate of the second sub-layer 320 may be less than or equal to 100 s⁻¹.

The greater the strain rate, the greater the increase in the elastic modulus of the film layer when the film layer is impacted. If the film layer is impacted, the elastic modulus of the film layer is obviously increased. For example, for the adhesive layer, such as OCA adhesive, the material itself is a high molecular adhesive material. The effect of modulus strengthening is easy to occur at different impact strengths. That is, the greater the impact strength, the stronger the self-viscoelastic effect, and the increase in the instantaneous modulus macroscopically may result in insufficient resistance to the longitudinal stress wave.

A material of the second sub-layer 320 may be a stress rate (e.g., a strain rate) independent material or a low stress rate (e.g., a low strain rate) material of the layer. That is, the material of the layer does not cause an increase in the modulus or an increase in the strength as the impact strength is changed under an impact load. The material of the layer can be capable of maintaining the stability and uniformity of the modulus under the impact load. Alternatively, the modulus of the material of the layer may be decreased with increasing of the impact strength under the impact load, thereby ensuring that the elastic modulus of the second sub-layer 320 cannot be increased significantly when the display device 100 is subjected to a strong impact, avoiding a significant decreasing in the ability of the second sub-layer 320 to absorb the longitudinal stress wave, ensuring absorption of the longitudinal stress wave, and facilitating obstruction of the propagation of the stress wave.

Methods for measuring the strain rate in a series of experiments for studying the dynamic mechanical properties of materials include a pendulum test (for example, an experiment of a strain rate 10E0˜10E2/s), a Hopkinson test (for example, an experiment of a strain rate 10E2˜10E4/s), an air gun (for example, an experiment of a strain rate 10E4˜10E6/s), and the like. Only some examples are shown herein, which are not limited to the present application.

In the experimental groups 5 and 8, the strain rate-independent material PDMS may be used to reduce the strain of the encapsulation layer to about 0.5% compared with the strain rate-increasing material TPU, indicating that the use of the stress rate-independent material or the low stress rate material as the second sub-layer 320 is more favorable for reducing the impact stress.

In some embodiments, a strain rate of the second sub-layer 320 may be 10 s⁻¹ to 100 s⁻¹.

In some embodiments, the material of the second sub-layer 320 may be selected from any of polyurethane, toluene diisocyanate, polydimethylsiloxane, cyclomethylsiloxane, aminosiloxane, polymethylphenylsiloxane, polyether polysiloxane copolymer, and the like. The material may be a stress rate (e.g., a strain rate) independent material or a low stress rate (e.g., a low strain rate) material of the layer. That is, the material of the layer does not cause an increase in modulus or an increase in strength as the impact strength is changed under the impact load. Such materials can also be modified to provide better chemical stability, electrical insulation, weatherability, and hydrophobicity, and have high shear resistance, and can be used for a long time at −50° C.˜200° C. Meanwhile, the materials have excellent physical properties, such as moisture insulation, damping, and shock absorption.

For example, an optically transparent elastomer material may be obtained by coupling a macromolecular polydimethylsiloxane-terminated reactive group with a curing agent and have a light transmittance greater than 93%, a refractive index greater than 1.4%, a high dielectric property, a good elasticity, and an elongation greater than 500% or more.

In some embodiments, the first sub-layer may be made of any one of polyimide, CPI, PET, or a high elastic modulus of an acryl polymer. Such a material may have a higher elastic modulus and advantageously form a high-low elastic modulus film layer in conjunction with the second sub-layer 320. Vibration wave reflection and transmission phenomena occur at an interface. The difference in propagation of the stress wave near the two film layers may be caused by the impedance difference between the two materials. The greater the impedance difference between the two materials, the stronger the reflection wave, and the less the stress waves that are transmitted into the low modulus layer and the more the stress waves that are returned reversely.

In some embodiments, referring to FIG. 2, the first sub-layer 310 may include a first layer 311 and a second layer 312, where the second layer 312 may be located at a side of the first layer 311 close to the display panel 200, and a hardness of the first layer 311 may be greater than a hardness of the second layer 312.

As the outermost layer of the display device 100, the first sub-layer 310 needs to have better wear and scratch resistance. Therefore, a high molecular hardening layer may be provided on the second layer 312. The first layer 311 may have a thickness of 2 μm to 5 μm. The first layer 311 may be made of a coating material, such as polyurethane, so that the first sub-layer 310 may have both scratch resistance and wear resistance while resisting impact stress with high modulus characteristics of the first layer 311, thereby further prolonging the service life of the display device 100.

In some embodiments, the first layer 311 may have a Mohs hardness of 6˜7.

In some embodiments, referring to FIG. 1, a thickness of the second sub-layer 320 may be greater than a thickness of the first sub-layer 310. The second sub-layer 320 may have a relatively low elastic modulus, which is more favorable for absorbing a longitudinal stress wave. The second sub-layer 320 may be configured to have a relatively thick thickness, so that the longitudinal stress wave can be more sufficiently absorbed, thereby reducing the energy of the longitudinal stress wave passing through the second sub-layer 320, ensuring absorption of the longitudinal stress wave, and the propagation of the stress waves may be prevented, thereby prolonging the service life of the display device 100.

In some embodiments, the first sub-layer 310 may have a thickness of 50 μm to 80 μm, and the second sub-layer 320 may have a thickness of 100 μm to 200 μm. In some embodiments, the first sub-layer 310 may have an elastic modulus of 2000 Mpa to 6000 Mpa, and the second sub-layer 320 may have an elastic modulus of 20 Mpa to 100 Mpa. The elastic modulus can be adjusted adaptively according to an actual situation that the display panel 100 may be, for example, a folding structure according to a radius of a folding angle for folding the display device 100.

In some embodiments, referring to FIG. 2, the display device 100 may include a bending region 101 and a planar region 102 located at both sides of the bending region 101, where the second sub-layer 320 includes a first portion 321 disposed in the bending region 101 and a second portion 322 disposed in the planar region 102, and an elastic modulus of the first portion 321 is less than an elastic modulus of the second portion 322.

The display device 100 may be a foldable structure, where the bending region 101 needs to have better bending performance, and the second sub-layer 320, as a film layer having a low elastic modulus, can be optimized for the bending performance of the bending region 101 on the basis of ensuring the impact resistance of the bending region 101, so that the elastic modulus of the first portion 321 in the bending region 101 is further reduced to improve the bending performance of the bending region 101, thereby reducing the risk of damage of the bending stress to the display panel 200 in the bending region 101 and prolonging the service life of the display device 100.

In some embodiments, the first portion 321 and the second portion 322 may be provided integrally or separately. If the second portion 322 and the first portion 321 are integrally provided, adjustment of the elastic modulus may be achieved by adjusting process conditions at which the first portion 321 and the second portion 322 are formed, such as a curing temperature, a curing rate, and the like, to achieve a structure in which the elastic modulus of the first portion 321 is less than the elastic modulus of the second portion 322.

In some embodiments, referring to FIGS. 1 to 2, the impact-resistance layer 300 may further include a third sub-layer 330 located at a side of the second sub-layer 320 away from the first sub-layer 310, where a ratio of an elastic modulus of the third sub-layer 330 to the elastic modulus of the second sub-layer 320 may be 20 to 300.

The elastic modulus of the third sub-layer 330 may be greater than that of the second sub-layer 320, and the first sub-layer 310, the second sub-layer 320, and the third sub-layer 330 constitute a high-low-high elastic modulus structure. The third sub-layer 330 serves as a film layer having a high elastic modulus and further facilitates absorption of a stress wave passing through the second sub-layer 320, and serves as a third main line of defense against impact and further facilitates prolonging the service life of the display device 100.

In some embodiments, a ratio of the elastic modulus of the third sub-layer to the elastic modulus of the second sub-layer may be 20 to 300.

If the elastic modulus of the third sub-layer is too small, it is not conducive to absorption of the longitudinal stress wave by the third sub-layer. If the difference between the elastic modulus of the second sub-layer and the elastic modulus of the third sub-layer is too large, that is, the elastic modulus of the third sub-layer is too large, it is not conducive to the bending performance of the display device. If the elastic modulus of the second sub-layer 320 is too small, for example, some adhesive layers, such as an optically clear adhesive (OCA) glue may have an elastic modulus in the order of Kpa, it is difficult to evacuate and absorb an impact energy by in-plane vibration of the second sub-layer 320 due to inherent viscous flow characteristics of the second sub-layer 320 when subjected to an impact. The ratio of the elastic modulus of the third sub-layer to the elastic modulus of the second sub-layer may be 20 to 300, e.g., any of 20, 50, 80, 100, 150, 200, 240, 250, 280, or 300.

In some embodiments, the elastic modulus of the third sub-layer 330 may be 2000 Mpa to 6000 Mpa. The elastic modulus of the third sub-layer may be larger, thereby facilitating absorption of the longitudinal stress wave by the third sub-layer.

The combination of high modulus+low modulus+high modulus may be designed in the experimental groups 8 and 9, and the strain of the encapsulation layer may be reduced to about 0.42%, indicating that the combination of the design may be beneficial to effectively reducing the impact stress wave.

In some embodiments, the elastic modulus of the third sub-layer 330 may be greater than the elastic modulus of the first sub-layer 310. As the third main line of defense against impact, the third sub-layer 330 may have better impact resistance. For the foldable display device 100, the elastic modulus of the third sub-layer 330 is higher, which is more favorable for reducing folds and improving a visual effect of the display device 100. The display panel 200 may have a relatively low elastic modulus, and be easily warped when the display panel 200 is attached. The elastic modulus of the third sub-layer 330 is relatively high, so that the attachment to the display panel 200 can be strengthened, thereby ensuring flatness of the film layer of the display device 100.

In some embodiments, referring to FIGS. 1 to 2, a thickness of the third sub-layer 330 may be less than or equal to a thickness of the first sub-layer 310. If the thickness of the third sub-layer 330 is too large, a neutral layer of the display device 100 may be moved away from the display panel 200. If the neutral layer is kept close to the display panel 200, a thicker film layer needs to be provided on the backlight side of the display panel 200, so that the overall thickness of the display device 100 may be thickened. On the one hand, it is not conducive to thinning of the display device 100. On the other hand, for the folding display device 100, the larger thickness of the display device 100 is also not conducive to bending of the display device 100. Therefore, the thickness of the third sub-layer 330 is less than or equal to the thickness of the first sub-layer 310, so that the impact on the neutral layer of the display device 100 may be reduced and the quality of the display device 100 may be ensured on the basis of ensuring impact-resistance performance of the third sub-layer 330.

In some embodiments, referring to FIGS. 1 to 2, the thickness of the third sub-layer 330 may be less than a thickness of the second sub-layer 320. The second sub-layer 320 may have a relatively low elastic modulus, which is more favorable for absorbing a longitudinal stress wave. The second sub-layer 320 is a relatively thick thickness, so that the longitudinal stress wave can be more sufficiently absorbed, thereby reducing the energy of the longitudinal stress wave passing through the second sub-layer 320, ensuring absorption of the longitudinal stress wave, and the propagation of the stress waves may be prevented, thereby prolonging the service life of the display device 100.

In some embodiments, the third sub-layer 330 may be made of any one of polyimide, CPI, PET, or a high elastic modulus of an acryl polymer. Such a material may have a higher elastic modulus, and a lateral stress wave may be propagated rapidly in the plane of the third sub-layer 330. A lateral material area of the third sub-layer 330 may be larger, which can facilitate that the lateral impact stress wave may release or diffuse the stress to a distal end of an impact region as the third sub-layer 330 may be vibrated or deformed in the plane of the third sub-layer 330.

In some embodiments, the third sub-layer 330 may have a thickness of 23 μm to 50 μm.

In some embodiments, referring to FIG. 2, the impact-resistance layer 300 may further include a fourth sub-layer 340 located at a side of the third sub-layer 330 away from the first sub-layer 310 and a fifth sub-layer 350 located at a side of the fourth sub-layer 340 away from the first sub-layer 310, where an elastic modulus of the fifth sub-layer 350 may be greater than the elastic modulus of the fourth sub-layer 340, and the elastic modulus of the third sub-layer 330 may be greater than the elastic modulus of the fourth sub-layer 340.

The more times the high and low elastic modulus film layers are laminated, the better the stress wave blocking effect in the vertical direction. The impact resistance performance of an impact-resistance layer 300 may be further improved by using the impact-resistance layer 300 having multi-layer high-low-high-low-high elastic modulus. An operation principle of the impact-resistance layer 300 having the high-low-high-low-high elastic modulus may be similar to that of the impact-resistance layer 300 having high-low-high elastic modulus.

By comparing the experimental groups 9 and 10, when the thickness of the whole impact-resistance layer 300 is not significantly changed, a lamination of film layers may be designed with high modulus+low modulus+high modulus+low modulus+high modulus, so that the strain of the encapsulation layer is reduced to about 0.41%, indicating that the strain of the encapsulation layer may be improved by combination of the multilayer, but not obvious, and that the lamination of the three layer is sufficient to absorb impact stress when the drop ball 110 is tested at a certain height. However, if a product having a better impact resistance is considered, the lamination of the multilayer can be adopted while taking bending performance into account.

In some embodiments, the number of sub-layers of the impact-resistance layer 300 may be greater, for example, six or seven layers, and the like, and will not be enumerated in the present application. However, it is still necessary to consider the balance between the thickness of film layers and the bending performance, and set in accordance with actual parameter requirements.

In some embodiments, a ratio of the elastic modulus of the third sub-layer to the elastic modulus of the fourth sub-layer may be 20 to 300.

If the elastic modulus of the fourth sub-layer is too large, it is not conducive to reflection of the longitudinal stress wave back to the third sub-layer to protect the display panel 200, which may cause more longitudinal stress waves to penetrate the display device 100. If the difference between the elastic modulus of the fourth sub-layer and the elastic modulus of the third sub-layer is too large, that is, the elastic modulus of the fourth sub-layer is too small, for example, some adhesive layers, such as an optically clear adhesive (OCA) glue may have an elastic modulus in the order of Kpa, it is difficult to evacuate and absorb an impact energy by in-plane vibration of the second sub-layer 320 due to inherent viscous flow characteristics of the second sub-layer 320 when subjected to an impact. The ratio of the elastic modulus of the third sub-layer to the elastic modulus of the fourth sub-layer may be 20 to 300, e.g., any of 20, 50, 80, 100, 150, 200, 240, 250, 280, or 300.

In some embodiments, the fourth sub-layer 340 may have an elastic modulus of 20 Mpa to 100 Mpa.

If the elastic modulus of the fourth sub-layer is too large, it is not conducive to reflection of the longitudinal stress wave back to the third sub-layer to protect the display panel 200, which may cause more longitudinal stress waves to penetrate the display device 100. If the difference between the elastic modulus of the fourth sub-layer and the elastic modulus of the third sub-layer is too large, that is, the elastic modulus of the fourth sub-layer is too small, for example, some adhesive layers, such as an optically clear adhesive (OCA) glue may have an elastic modulus in the order of Kpa, it is difficult to evacuate and absorb an impact energy by in-plane vibration of the fourth sub-layer due to inherent viscous flow characteristics of the fourth sub-layer when subjected to an impact.

In some embodiments, a ratio of the elastic modulus of the fifth sub-layer to the elastic modulus of the fourth sub-layer may be 20 to 300.

If the elastic modulus of the fifth sub-layer is too small, it is not conducive to absorption of the longitudinal stress wave. If the elastic modulus of the fifth sub-layer is too large, it is not conducive to bending performance of the display device. If the elastic modulus of the fourth sub-layer is too small, it is not conducive to for example, some adhesive layers, such as an optically clear adhesive (OCA) glue may have an elastic modulus in the order of Kpa, it is difficult to evacuate and absorb an impact energy by in-plane vibration of the second sub-layer 320 due to inherent viscous flow characteristics of the second sub-layer 320 when subjected to an impact. The ratio of the elastic modulus of the fifth sub-layer to the elastic modulus of the fourth sub-layer may be 20 to 300, e.g., any of 20, 50, 80, 100, 150, 200, 240, 250, 280, or 300.

In some embodiments, the elastic modulus of the fifth sub-layer may be 2000 Mpa to 6000 Mpa. The elastic modulus of the fifth sub-layer may be larger, thereby facilitating absorption of the longitudinal stress wave by the fifth sub-layer.

In some embodiments, the elastic modulus of the fifth sub-layer 350 is greater than the elastic modulus of the first sub-layer 310 and the elastic modulus of the third sub-layer 330. The fifth sub-layer 350 may have better impact resistance. For the foldable display device 100, the elastic modulus of the fifth sub-layer 350 is higher, which is more favorable for reducing folds and improving a visual effect of the display device 100. The display panel 200 may have a relatively low elastic modulus, and be easily warped when the display panel 200 is attached. The elastic modulus of the fifth sub-layer 350 is relatively high, so that the attachment to the display panel 200 can be strengthened, thereby ensuring flatness of the film layer of the display device 100.

In some embodiments, referring to FIG. 2, a sum of the thickness of the third sub-layer 330 and the thickness of the fifth sub-layer 350 may be less than or equal to the thickness of the first sub-layer 310.

Specifically, the sum of the thickness of the third sub-layer 330 and the thickness of the fifth sub-layer 350 is less than or equal to the thickness of the second layer 312 of the first sub-layer 310. If the sum of the thickness of the third sub-layer 330 and the thickness of the fifth sub-layer 350 is too large, which may cause the neutral layer of the display device 100 to move away from the display panel 200. Therefore, the sum of the thickness of the third sub-layer 330 and the thickness of the fifth sub-layer 350 is less than or equal to the thickness of the first sub-layer 310, and the impact on the neutral layer of the display device 100 is reduced on the basis of the impact resistance of the third sub-layer 330 and the fifth sub-layer 350, thereby ensuring the quality of the display device 100.

In some embodiments, referring to FIG. 2, the thickness of the fourth sub-layer 340 is greater than the thickness of the third sub-layer 330, and the thickness of the fourth sub-layer 340 is greater than the thickness of the fifth sub-layer 350.

The fourth sub-layer 340 may have a relatively low elastic modulus, which is more favorable for absorbing a longitudinal stress wave. The fourth sub-layer 340 may be configured to have a relatively thick thickness, so that the longitudinal stress wave can be more sufficiently absorbed, thereby reducing the energy of the longitudinal stress wave passing through the fourth sub-layer 340, ensuring absorption of the longitudinal stress wave, and the propagation of the stress waves may be prevented, thereby prolonging the service life of the display device 100.

In some embodiments, referring to FIG. 2, a thickness of the fourth sub-layer 340 may be greater than a thickness of the second sub-layer 320.

If the thickness of the fourth sub-layer 340 is too large, the neutral layer of the display device 100 is moved away from the display panel 200. If the neutral layer is kept close to the display panel 200, a thicker film layer needs to be disposed on a backlight side of the display panel 200, so that the overall thickness of the display device 100 may be thickened. On the one hand, it is not conducive to thinning of the display device 100. On the other hand, for a folding display device 100, the larger thickness of the display device 100 is also not conducive to bending of the display device 100. Therefore, the thickness of the fourth sub-layer 340 is less than the thickness of the second sub-layer 320, and the impact on the neutral layer of the display device 100 is reduced on basis of the impact resistance of the fourth sub-layer 340, thereby ensuring the quality of the display device 100.

In some embodiments, the fourth sub-layer 340 may have a thickness of 50 μm to 150 μm. the fifth sub-layer 350 may have a thickness of 15 μm to 25 μm.

In some embodiments, a strain rate of the fourth sub-layer is less than or equal to 100 s⁻¹.

The greater the strain rate, the greater the increase in the elastic modulus of the film layer when the film layer is impacted. If the film layer is impacted, the elastic modulus of the film layer is obviously increased. For example, for the adhesive layer, such as OCA adhesive, the material itself is a high molecular adhesive material. The effect of modulus strengthening is easy to occur at different impact strengths. That is, the greater the impact strength, the stronger the self-viscoelastic effect, and the increase in the instantaneous modulus macroscopically may result in insufficient resistance to the longitudinal stress wave. A material of the fourth sub-layer may be a stress rate (e.g., a strain rate) independent material or a low stress rate (e.g., a low strain rate) material of the layer. That is, the material of the layer does not cause an increase in the modulus or an increase in the strength as the impact strength is changed under an impact load. The material of the layer can be capable of maintaining the stability and uniformity of the modulus under the impact load. Alternatively, the modulus of the material of the layer may be decreased with increasing of the impact strength under the impact load, thereby ensuring that the elastic modulus of the fourth sub-layer cannot be increased significantly when the display device 100 is subjected to a strong impact, avoiding a significant decreasing in the ability of the fourth sub-layer to absorb the longitudinal stress wave, ensuring absorption of the longitudinal stress wave, and facilitating obstruction of the propagation of the stress wave.

In some embodiments, a strain rate of the fourth sub-layer is 10 s⁻¹ to 100 s⁻¹.

In some embodiments, the material of the fourth sub-layer may be selected from any of polyurethane, toluene diisocyanate, polydimethylsiloxane, cyclomethylsiloxane, aminosiloxane, polymethylphenylsiloxane, polyether polysiloxane copolymer, and the like. The material may be a stress rate (e.g., a strain rate) independent material or a low stress rate (e.g., a low strain rate) material of the layer. That is, the material of the layer does not cause an increase in modulus or an increase in strength as the impact strength is changed under the impact load. Such materials can also be modified to provide better chemical stability, electrical insulation, weatherability, and hydrophobicity, and have high shear resistance, and can be used for a long time at −50° C.˜200° C. Meanwhile, the materials have excellent physical properties, such as moisture insulation, damping, and shock absorption.

In some embodiments, the fifth sub-layer may be made of any one of polyimide, CPI, PET, or a high elastic modulus of an acryl polymer. Such a material may have a higher elastic modulus, and a lateral stress wave may be propagated rapidly in the plane of the fifth sub-layer. A lateral material area of the fifth sub-layer may be larger, which can facilitate that the lateral impact stress wave may release or diffuse the stress to a distal end of an impact region as the fifth sub-layer may be vibrated or deformed in the plane of the fifth sub-layer.

In some embodiments, referring to FIG. 2, the display device 100 includes a bending region 101 and a planar region 102 located at both sides of the bending region 101, where the fourth sub-layer 340 includes a third portion 341 disposed in the bending region 101 and a fourth portion 342 disposed in the planar region 102, and an elastic modulus of the third portion 341 is less than an elastic modulus of the fourth portion 342.

The display device 100 may be a foldable structure, where the bending region 101 needs to have better bending performance, and the fourth sub-layer 340, as a film layer having a low elastic modulus, can be optimized for the bending performance of the bending region 101 on the basis of ensuring the impact resistance of the bending region 101, so that the elastic modulus of the third portion 321 in the bending region 101 is further reduced to improve the bending performance of the bending region 101, thereby reducing the risk of damage of the bending stress to the display panel 200 in the bending region 101 and prolonging the service life of the display device 100.

In some embodiments, referring to FIGS. 1 and 2, the impact-resistance layer 300 may further include an adhesive layer 400 disposed between any two adjacent film layers of the first sub-layer 310, the second sub-layer 320, the third sub-layer 330, the fourth sub-layer 340, and the fifth sub-layer 350.

For example, referring to FIG. 2, the impact-resistance layer 300 may further include a first adhesive layer 410 disposed between the first sub-layer 310 and the second sub-layer 320, a second adhesive layer 420 disposed between the second sub-layer 320 and a third sub-layer 330, a third adhesive layer 430 disposed between the third sub-layer 330 and the fourth sub-layer 340, and a fourth adhesive layer 440 disposed between the fourth sub-layer 340 and the fifth sub-layer 350. The adhesive layer 400 may be an optical adhesive layer.

An optical adhesive material of the adhesive layer 400 can effectively absorb a bending strain of each of the film layers in a bending state, and divide the entire display device into a plurality of neutral layers. In FIG. 9, the neutral layers are shown by dashed lines, so that each of the layers may be in a state where the stress and the strain are small, thereby ensuring the bending performance.

In some embodiments, the elastic modulus of any of the first sub-layer 310, the second sub-layer 320, the third sub-layer 330, the fourth sub-layer 340, and the fifth sub-layer 350 may be greater than the elastic modulus of any of the first adhesive layer 410, the second adhesive layer 420, the third adhesive layer 430, and the fourth adhesive layer 440.

In some embodiments, the adhesive layer closer to the display panel 200 may have the higher elastic modulus. For example, the elastic modulus of the second adhesive layer 420 may be greater than the elastic modulus of the first sub-layer 310. Better impact resistance can be obtained. Since the display panel 200 may have a relatively low elastic modulus and be easily warped when the display panel 200 is attached. The adhesive layer having the higher elastic modulus may be configured to be closer to the display panel, so that the attachment to the display panel 200 can be strengthened, thereby ensuring flatness of the film layer of the display device 100.

In some embodiments, the display panel 200 may be a liquid crystal display panel 200 or a self-emitting display panel 200.

In some embodiments, the display panel 200 may be a liquid crystal display panel 200, which further includes a liquid crystal layer, a color film layer, an upper polarizing layer, and a lower polarizing layer. The display device may further include a backlight unit corresponding to the display panel 200.

In some embodiments, the display panel 200 may be a self-emitting display panel 200.

The display panel 200 further includes a light emitting device layer.

In some embodiments, referring to FIG. 1, the display panel 200 may be a self-emitting display panel 200. The display device 100 may further include a polarizing layer 360 provided on a light-emitting side of the display panel 200. The polarizing layer 360 may also serve as a film layer in the impact-resistance layer 300.

In some embodiments, the display device 100 may further include a support layer 500 located on a side of the display panel 200 away from the light-emitting side, where the support layer 500 includes a first support sub-layer 510, a second support sub-layer 520, and a third support sub-layer 530. The first support sub-layer 510 may be made of a backsheet material, such as an aluminum-plastic sheet. The second support sub-layer 520 may be a polymeric material such as PET. The third support sub-layer 530 may be made of a material having a high elastic modulus, such as stainless steel.

In some embodiments, the first support sub-layer 510, the second support sub-layer 520, and the third support sub-layer 530 may be bonded by an adhesive layer.

In some embodiments, referring to FIGS. 1 and 2, the third support sub-layer 530 may include a plurality of stress releasing holes 531 disposed in the bending region 101. The stress releasing holes 531 may be extended through the third support sub-layer 530, or may be not extended through the third support sub-layer 530. Parameters such as a depth and a density of the third support sub-layer 530 may be provided according to an actual case, which are not specifically limited herein.

In some embodiments, referring to FIGS. 1 and 2, the display device 100 may further include a dustproof reinforcing layer 540 disposed on a side of the third support sub-layer 530 away from the display panel 200, where the dustproof reinforcing layer 540 may be disposed corresponding to the bending region 101.

In the present application, the impact-resistance layer including at least two sub-layers respectively having a high elastic modulus and a low elastic modulus may be disposed on the display panel. When the display device is impacted, an impact energy is propagated in a stress wave including a lateral stress wave and a longitudinal stress wave in a lateral direction and a longitudinal direction, respectively. The stress wave first contacts the high elastic modulus film layer to rapidly propagate the lateral stress wave within the plane of the first sub-layer, and the lateral stress wave can be rapidly absorbed by a smaller deformation of the first sub-layer. The longitudinal stress wave continues to be propagated inward in a direction perpendicular to the display device, and when the longitudinal stress wave contacts the second sub-layer having the low elastic modulus, the impact energy can be easily absorbed by a larger deformation of the second sub-layer. Meanwhile, the stress wave is more easily propagated in the film layer having a larger elastic modulus, and since the elastic modulus of the second sub-layer is greater than the elastic modulus of the first sub-layer, the longitudinal stress wave is more easily reflected back to the first sub-layer, thereby slowing the tendency that the longitudinal stress wave is further propagated inward in the direction perpendicular to the display device and being more advantageous to protect the display panel and prolong the service life of the display device.

The present application provides a display device. The display device includes a display panel and an impact-resistance layer. The impact-resistance layer includes at least two sub-layers, two adjacent sub-layers of the sub-layers are bonded by an adhesive layer, the at least two sub-layers includes a first sub-layer and a second sub-layer between the first sub-layer and the display panel, the ratio of the elastic modulus of the first sub-layer to the elastic modulus of the second sub-layer is 20 to 300, and the material of the first sub-layer is different from the material of the second sub-layer. In the present application, by disposing the impact-resistance layer including at least two layers having high-low elastic modulus on the display panel, when the display device is subjected to an impact, the impact energy is propagated in a stress wave including a lateral stress wave and a longitudinal stress wave, and the lateral stress wave is propagated rapidly in the plane of the first sub-layer. The first sub-layer can rapidly absorb the stress wave in the horizontal direction by a small deformation. The second sub-layer absorbs the impact energy more easily by a large deformation, and the longitudinal stress wave is more easily reflected back to the first sub-layer.

It can be understood that, for those ordinary skilled in the art, equivalent replacements or changes can be made according to the technical solutions and inventive concepts of the present application, and all such changes or replacements should fall within the protection scope of the claims appended to the present application.

What is claimed is:

1. A display device, comprising:
a display panel; and
an impact-resistance layer provided on a light-emitting side of the display panel;
wherein the impact-resistance layer comprises at least two sub-layers, two adjacent sub-layers of the sub-layers are bonded by an adhesive layer, the at least two sub-layers comprises a first sub-layer and a second sub-layer located on one side of the first sub-layer close to the display panel, a ratio of an elastic modulus of the first sub-layer to an elastic modulus of the second sub-layer is 20 to 300, and a material of the first sub-layer is different from a material of the second sub-layer.

2. The display device of claim 1, wherein a strain rate of the second sub-layer is less than or equal to 100 s⁻¹.

3. The display device of claim 2, wherein the second sub-layer is made of any one of polyurethane, toluene diisocyanate, polydimethylsiloxane, cyclomethylsiloxane, aminosiloxane, polymethylphenylsiloxane, or polyether polysiloxane copolymer.

4. The display device of claim 1, wherein a thickness of the second sub-layer is greater than a thickness of the first sub-layer.

5. The display device of claim 1, wherein the display device comprises a bending region and a planar region located at both sides of the bending region,
the second sub-layer comprises a first portion disposed in the bending region and a second portion disposed in the planar region, and
an elastic modulus of the first portion is less than an elastic modulus of the second portion.

6. The display device of claim 1, wherein the impact-resistance layer further comprises a third sub-layer located at one side of the second sub-layer away from the first sub-layer, and a ratio of an elastic modulus of the third sub-layer to the elastic modulus of the second sub-layer is 20 to 300.

7. The display device of claim 6, wherein the elastic modulus of the third sub-layer is greater than the elastic modulus of the first sub-layer.

8. The display device of claim 6, wherein a thickness of the third sub-layer is less than or equal to a thickness of the first sub-layer.

9. The display device of claim 6, wherein a thickness of the third sub-layer is less than a thickness of the second sub-layer.

10. The display device of claim 6, wherein the first sub-layer or the third sub-layer is made of any one of polyimide, polyethylene terephthalate, or acryl.

11. The display device of claim 6, wherein the impact-resistance layer further comprises a fourth sub-layer located at one side of the third sub-layer away from the first sub-layer and a fifth sub-layer located at one side of the fourth sub-layer away from the first sub-layer; and
the elastic modulus of the fifth sub-layer is greater than the elastic modulus of the fourth sub-layer, and the elastic modulus of the third sub-layer is greater than the elastic modulus of the fourth sub-layer.

12. The display device of claim 11, wherein a ratio of the elastic modulus of the fifth sub-layer to the elastic modulus of the fourth sub-layer is 20 to 300, and a ratio of the elastic modulus of the third sub-layer to the elastic modulus of the fourth sub-layer is 20 to 300.

13. The display device of claim 11, wherein the elastic modulus of the fifth sub-layer is greater than the elastic modulus of the first sub-layer, and the elastic modulus of the fifth sub-layer is further greater than the elastic modulus of the third sub-layer.

14. The display device of claim 11, wherein a sum of a thickness of the third sub-layer and a thickness of the fifth sub-layer is less than or equal to a thickness of the first sub-layer.

15. The display device of claim 11, wherein a thickness of the fourth sub-layer is greater than a thickness of the third sub-layer, and the thickness of the fourth sub-layer is further greater than a thickness of the fifth sub-layer.

16. The display device of claim 11, wherein a thickness of the fourth sub-layer is less than a thickness of the second sub-layer.

17. The display device of claim 11, wherein the display device comprises a bending region and a planar region located at both sides of the bending region,
the fourth sub-layer comprises a third portion disposed in the bending region and a fourth portion disposed in the planar region, and
an elastic modulus of the third portion is less than an elastic modulus of the fourth portion.

18. The display device of claim 11, wherein a strain rate of the fourth sub-layer is less than or equal to 100 s⁻¹.

19. The display device of claim 18, wherein the fourth sub-layer is made of any one of polyurethane, toluene diisocyanate, polydimethylsiloxane, cyclomethylsiloxane, aminosiloxane, polymethylphenylsiloxane, or polyether polysiloxane copolymer; and
the fifth sub-layer is made of any one of polyimide, polyethylene terephthalate, or acryl.

20. The display device of claim 1, wherein the first sub-layer includes a first layer and a second layer located at one side of the first layer close to the display panel; and
a hardness of the first layer is greater than a hardness of the second layer.
